(19) United States
(12) Patent Application Publication
(10) Pub. No.: US 2025/0093383 A1
(43) Pub. Date: Mar. 20, 2025

(54) REMOVABLE HIGH-SPEED SIGNAL MEASUREMENT DEVICE

(71) Applicant: INTERNATIONAL BUSINESS MACHINES CORPORATION, Armonk, NY (US)

(72) Inventors: Kyle Olson, Lagrangeville, NY (US); Matteo Cocchini, New York, NY (US)

(21) Appl. No.: 18/467,894

(22) Filed: Sep. 15, 2023

(51) Int. Cl. G01R 1/067

(52) U.S. Cl. CPC G01R 1/06722

(57) ABSTRACT

A high-speed signal measurement system includes a printed circuit board and a measurement device. The printed circuit board includes a conductive pad. The measurement device is configured to be removably coupled to the printed circuit board. The measurement device is configured to establish an electrical connection between a conductive probe tip and the conductive pad. The measurement device includes a clamp movable between an open position in which the measurement device is configured to removably receive the conductive probe tip and a closed position in which the measurement device is configured to retain the conductive probe tip. The measurement device further includes a spring mechanism configured to exert a spring force to maintain the electrical connection between the conductive probe tip and the conductive pad when the measurement device is coupled to the printed circuit board and the clamp is in the closed position.

### BACKGROUND

The present disclosure relates generally to the field of electronic equipment and systems, and more particularly to electronic equipment and systems configured to perform high-speed signal measurements.

A printed circuit board (PCB) is a medium used to electrically connect components to one another in a circuit. Measuring the signals propagated by the PCB at various locations and connections in the PCB enables determination of whether the signals are being propagated correctly.

### SUMMARY

Embodiments of the present disclosure include a high-speed signal measurement system. The high-speed signal measurement system includes a printed circuit board and a measurement device. The printed circuit board includes a conductive pad. The measurement device is configured to be removably coupled to the printed circuit board. The measurement device is configured to establish an electrical connection between a conductive probe tip and the conductive pad. The measurement device includes a clamp movable between an open position in which the measurement device is configured to removably receive the conductive probe tip and a closed position in which the measurement device is configured to retain the conductive probe tip. The measurement device further includes a spring mechanism configured to exert a spring force to maintain the electrical connection between the conductive probe tip and the conductive pad when the measurement device is coupled to the printed circuit board and the clamp is in the closed position.

Embodiments of the present disclosure further include a high-speed signal measurement device. The high-speed signal measurement device includes a housing configured to be removably coupled to a printed circuit board. The high-speed signal measurement device further includes a clamp pivotally coupled to the housing so as to be rotatable between an open position in which the measurement device is configured to receive a conductive probe tip and a closed position in which the measurement device is configured to retain the conductive probe tip. The high-speed signal measurement device further includes a spring mechanism configured to establish an electrical connection between a conductive pad on the printed circuit board and the conductive probe tip when the housing is coupled to the printed circuit board and the clamp is in the closed position.

Embodiments of the present disclosure further include a high-speed signal measurement device. The high-speed signal measurement device includes a housing configured to be removably coupled to a printed circuit board. A height of the housing extends from an uppermost surface of the housing to a lowermost surface of the housing. The high-speed signal measurement device further includes a clamp pivotally coupled to the uppermost surface so as to be rotatable between an open position in which the measurement device is configured to receive a conductive probe tip and a closed position in which the measurement device is configured to retain the conductive probe tip. The high-speed signal measurement device further includes a spring mechanism configured to exert a spring force in a direction perpendicular to the lowermost surface to establish an electrical connection between a conductive pad on the printed circuit board and the conductive probe tip when the housing is coupled to the printed circuit board and the clamp is in the closed position.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1A illustrates a front view of an example high-speed signal measurement device, in accordance with embodiments of the present disclosure.

FIG. 1B illustrates a side view of the example high-speed signal measurement device shown in FIG. 1A, in accordance with embodiments of the present disclosure.

FIG. 2 illustrates a cross-sectional view of the example high-speed signal measurement device shown in FIGS. 1A and 1B, in accordance with embodiments of the present disclosure.

FIG. 3 illustrates a cross-sectional view of the example high-speed signal measurement device shown in FIG. 2 within a high-speed signal measurement system, in accordance with embodiments of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the invention.

### DETAILED DESCRIPTION

Aspects of the present disclosure relate generally to the field of electronic equipment and systems configured to perform measurements of high-speed signals on a printed circuit board (PCB). A PCB is a medium used to electrically connect components to one another in a circuit. It takes the form of a laminated sandwich structure of conductive and insulating layers. Each of the conductive layers is designed with a functional artwork pattern of traces, planes, and other features (similar to wires on a flat surface) etched from one or more sheet layers of conductive material (typically copper) laminated onto and/or between sheet layers of a non-conductive substrate. Electrical components may be fixed to conductive pads on the outer layers in the shape designed to accept the component's terminals, and vias enable interconnections between layers. PCBs are used in nearly all electronic products. PCBs require additional design effort to lay out the circuit, but manufacturing and assembly can be automated.

As PCBs are utilized to handle increasing signal speeds, it becomes increasingly important to measure the signal at various locations and connections in the PCB to determine whether the signal is being propagated correctly. Signals with frequencies ranging from 50 MHz to as high as 3 GHz are considered high-speed signals. As signal speed increases, the likelihood of higher frequency impacts also increases, which can cause issues such as attenuation, crosstalk, reflection, switching issues, and impedance mismatch, for example. Ideally, in a PCB, a signal should travel from a source to a load without being altered. However, issues such as those mentioned above that arise with increasing signal speed can cause distortions and losses in the signal between the source and the load. High-speed signal measurement devices and systems are used to measure such high-speed signals to provide information pertaining to signal integrity.

Typical existing high-speed signal measurement includes soldering probe tips to various locations on a PCB. However, this type of soldering requires the time and skill of an advanced technician who is capable of performing the small-scale, precision soldering. Additionally, the resulting solder points are relatively permanent. Accordingly, the probe tips are difficult to attach, and are also difficult to detach once the measurements have been performed. Furthermore, each time soldering is performed on the PCB introduces the risk of damaging the PCB and/or its traces due to the exposure to heat from the soldering. Moreover, measuring differential signals requires two solder points for each signal measurement. For high-speed signal measurement, which utilizes measurements in many locations, the total number of solder points is significant, and each one carries the risk of damage to the PCB.

It is advantageous to develop a system and/or device for high-speed signal measurements that does not require the time and skill of an advanced soldering technician. It is further advantageous to develop a system and/or device for high-speed signal measurements that is not difficult to attach and difficult to detach. It is further advantageous to develop a system and/or device for high-speed signal measurements that does not introduce the risk of damage due to heat exposure for each signal measurement. Therefore, it is advantageous to develop a system and/or device for high-speed signal measurements that does not require soldering probe tips to the PCB.

Some existing solderless high-speed signal measurement approaches utilize a complex interface device, including integrated probe tips, which is mounted onto a mating connector that is integrally formed on the PCB. However, such existing approaches require significant consideration in the PCB layout design to accommodate the complex interface devices and mating connectors. Additionally, to receive the interface devices, the mating connectors formed on the PCB have complex footprints that introduce signal reflections, generating their own signal interference issues. Furthermore, such approaches are not suitable for mid bus probing. Instead, such approaches are applicable for test vehicles.

Accordingly, it is advantageous to develop a solderless high-speed signal measurement system and/or device which do not require significant consideration in the PCB layout design to accommodate complex interface devices and mating connectors. Additionally, it is advantageous to develop a solderless high-speed signal measurement system and/or device which minimizes the generation of its own signal interference issues. Additionally, it is advantageous to develop a solderless high-speed signal measurement system and/or device which is suitable for mid bus probing and is not limited to test vehicles but is also able to test production PCBs.

It is to be understood that the aforementioned advantages are example advantages and should not be construed as limiting. Embodiments of the present disclosure can contain all, some, or none of the aforementioned advantages while remaining within the spirit and scope of the present disclosure.

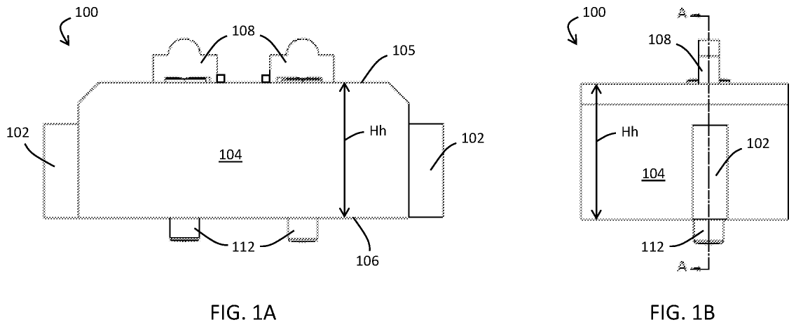

Turning now to the figures, FIGS. 1A and 1B depict an example high-speed signal measurement device 100 according to at least some illustrative embodiments of the present disclosure. FIG. 1A depicts a front plan view of the example device 100 and FIG. 1B depicts a side elevation view of the example device 100.

As described in further detail below, the example high-speed signal measurement device 100 utilizes a removable housing 104 that is configured to be easily attached and detached from a PCB. As used herein, the term “removable” refers to the ability to be easily attached and detached when intended by a user without causing damage to either the primary object being attached or detached or the secondary object which the primary object is being attached to/detached from. As described in further detail below, the housing 104 includes mounting components 102 configured to enable such removable attachment and detachment of the housing 104 from the PCB.

The housing 104 extends from an uppermost surface 105 to a lowermost surface 106 such that the height Hh of the housing 104 is defined by the uppermost surface 105 and the lowermost surface 106 and extends from the uppermost surface 105 to the lowermost surface 106. Overall, the housing 104 has a simple, streamlined configuration that minimizes the generation of its own signal interference issues.

As described in further detail below, the device 100 further includes clamps 108 configured to removably receive probe tips to perform signal measurements. As described in further detail below, the device 100 further includes spring mechanisms 112 configured to ensure robust contact between the received probe tips and the PCB traces for which the signals are measured.

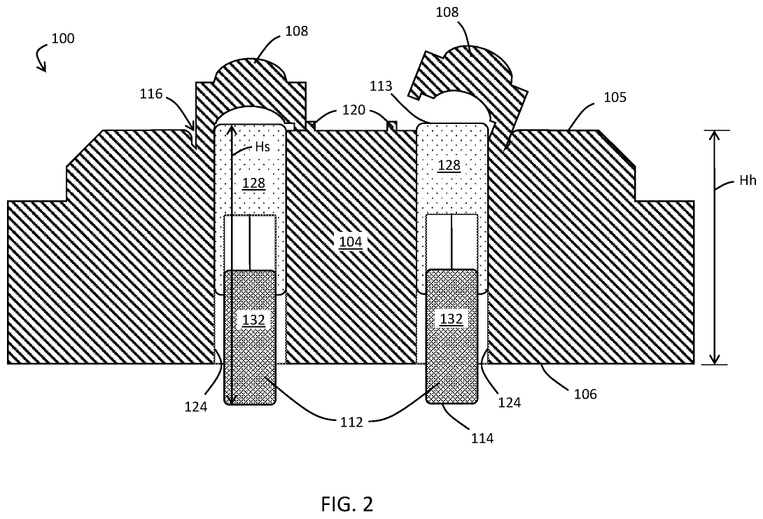

FIG. 2 depicts a cross-sectional view of the device 100 cut along the line A-A shown in FIG. 1B. As shown in FIG. 2, the device 100 includes at least one clamp 108 arranged on the uppermost surface 105 of the housing 104. In accordance with at least one embodiment of the present disclosure, the device 100 can include two clamps 108. Such embodiments enable simultaneous measurements from two probe tips such as, for example, for differential signals. Alternative embodiments of the present disclosure can include more or fewer than two clamps 108; each clamp 108 configured to removably receive one probe tip. Each clamp 108 is movable between an open position in which the measurement device 100 is configured to removably receive a conductive probe tip and a closed position in which the measurement device is configured to retain the conductive probe tip. In FIG. 2, the leftmost clamp 108 is in the closed position and the rightmost clamp 108 is in the open position.

In the embodiment shown in FIG. 2, the clamps 108 are formed together with the housing 104. In other words, the clamps 108 are integrally formed with the housing 104. As used herein, the term “integrally formed” refers to being a single piece that is not separable except by causing damage. In particular, each of the clamps 108 can be formed so as to flex to hinge relative to the housing 104 at a connection point 116 whereat the material that forms the clamps 108 and the housing 104 is relatively thin. In other words, the clamps 108 are pivotally connected to the housing such that the clamps 108 are configured to rotate relative to the housing 104 about an axis that is located in the connection point 116. Accordingly, each of the clamps 108 is configured to move between the open position and the closed position by rotating relative to the housing 104.

In accordance with alternative embodiments of the present disclosure, the clamps 108 can be formed independently of the housing 104 and coupled to the housing 104 so as to hinge relative to the housing 104 at a connection point that is substantially similar to the connection point 116. However, in such embodiments, each connection point is formed by the coupling of the respective clamp 108 to the housing 104 rather than being formed by a relatively thin area of material.

Each of the clamps 108 is configured to be retained in the closed position by a latch 120. The latches 120 are configured to be engaged and released such that the clamps 108 are able to be removably retained in the closed position and then also able to be released into the open position. Accordingly, a user can engage and release each of the latches 120, thereby opening and closing the respective clamps 108 as desired to retain the clamps in the closed position or release them into the open position. In accordance with at least one embodiment of the present disclosure, the latches 120 are configured to be actuated (e.g., engaged and/or released) using a tool. Such embodiments enable actuation of the latches 120 when the probe area (and therefore the housing 104 and/or the clamps 108) is sufficiently small that the latches 120 are too small to be reliably actuatable by a user's finger.

In accordance with at least one embodiment of the present disclosure, the latches 120 are integrally formed with the housing 104. In accordance with at least one alternative embodiment of the present disclosure, the latches 120 can be formed separately from the housing 104 and coupled thereto. In accordance with at least one further alternative embodiment, the latches 120 can be formed on or coupled to the clamps 108 instead of the housing 104. In accordance with at least one further alternative embodiment of the present disclosure, the latches 120 can be formed having two mating parts. In accordance with such embodiments, one portion of each latch 120 can be formed on or coupled to the housing 104 and one portion of each latch 120 can be formed on or coupled to the respective clamp 108. Each latch 120 is configured to engage the respective clamp 108 in a known manner to removably retain the clamp 108 in the closed position. Accordingly, the latches 120 are not discussed in further detail herein.

For embodiments in which the clamps 108 are integrally formed with the housing 104, the clamps 108 and the housing 104 can be formed by, for example, additive manufacturing. Similarly, for embodiments in which the latches 120 are integrally formed with the housing 104 and/or the clamps 108, the latches 120 can be formed by, for example, additive manufacturing.

As shown in FIG. 2, each clamp 108 is configured to cooperate with a respective spring mechanism 112. Each spring mechanism 112 is arranged within a respective opening 124 formed in the housing 104. Each opening 124 is formed so as to extend through the entire height Hh of the housing 124. Accordingly, each opening 124 is formed through both the uppermost surface 105 and the lowermost surface 106 of the housing 104. Accordingly, each opening 124 can be referred to as being in the uppermost surface 105 and the lowermost surface 106.

Each spring mechanism 112 extends through the respective opening 124 such that an uppermost surface 113 of the spring mechanism 112 is arranged above the uppermost surface 105 of the housing 104 and a lowermost surface 114 of the spring mechanism 112 is arranged below the lowermost surface 106 of the housing 104. Accordingly, each spring mechanism 112 has a height Hs, which extends from the uppermost surface 113 to the lowermost surface 114, that is greater than the height Hh of the housing 104.

Each spring mechanism 112 is configured to electrically conduct a signal from the lowermost surface 114 to the uppermost surface 113. Accordingly, at least some portions of the spring mechanism 112, including the lowermost surface 114 and the uppermost surface 113, are made of an electrically conductive material.

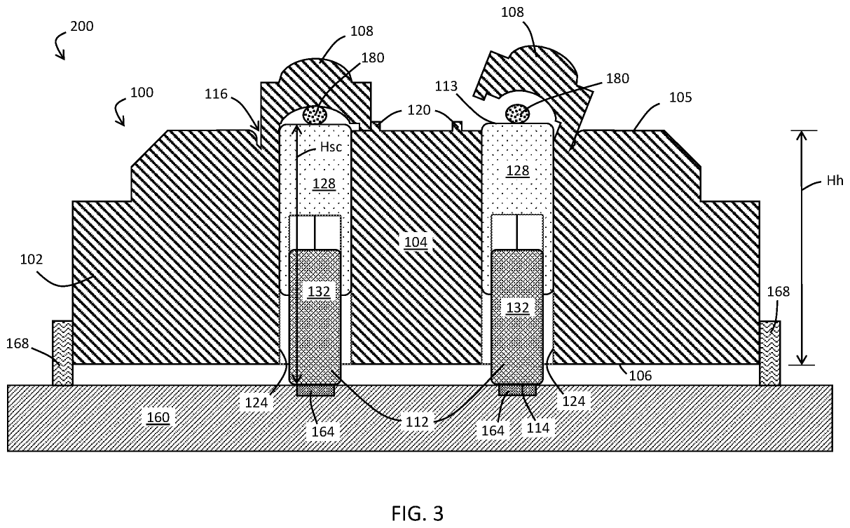

In accordance with the embodiment shown in FIG. 2, each spring mechanism 112 includes an upper portion 128 and a lower portion 132. In such embodiments, the upper portion 128 of each spring mechanism 112 remains stationary relative to the housing 104 and the lower portion 132 of each spring mechanism 112 moves relative to the housing 104. Accordingly, each spring mechanism 112 is movable between an expanded position (shown in FIG. 2) and a compressed position (shown in FIG. 3).

FIG. 3 illustrates the device 100 coupled to a PCB 160. As described in further detail below, when the device 100 is coupled to a PCB 160, the spring mechanisms 112 are in the compressed position and are storing potential energy as a spring force in a direction perpendicular to the lowermost surface 106 of the housing 104. Conversely, when in the expanded position (shown in FIG. 2), the spring mechanisms 112 are not storing potential energy as a spring force.

When the spring mechanism 112 is in the expanded position, the lower portion 132 extends farther from the upper portion 128 than when the spring mechanism 112 is in the compressed position such that the lower surface 114 of the spring mechanism 112 extends farther from the uppermost surface 113 of the spring mechanism 112. Accordingly, when the spring mechanism 112 is in the compressed position, the spring mechanism 112 has a height Hsc (shown in FIG. 3) that is less than the height Hs (shown in FIG. 2) of the spring mechanism 112 in the expanded position.

In accordance with the illustrative embodiments described herein, the height Hs (and Hsc) of the spring mechanism 112 is greater than the height Hh of the housing 104. However, in accordance with at least one alternative embodiment of the present disclosure, the spring mechanism 112 could have a height Hsc in the compressed position (shown in FIG. 3) that is substantially equal to the height Hh of the housing 104. In such embodiments, the spring mechanism 112 can be arranged in the housing 104 such that the uppermost surface 113 of the spring mechanism 112 is substantially coplanar with or lower than the uppermost surface 105 of the housing 104. Additionally or alternatively, the housing 104 can be configured to couple to the PCB 160 such that the lowermost surface 106 of the housing 104 is nearer to or in contact with the PCB 160. In other words, in such embodiments, the surface mounting components 168 can have a smaller height than is shown in FIG. 3 and/or can be configured so as to cooperate with the mounting components 102 of the housing such that the lowermost surface 106 of the housing 104 is nearer to or in contact with the PCB 160.

As described above, in the embodiment shown in FIGS. 2 and 3, the spring mechanisms 112 are configured as compression springs having one stationary portion (upper portion 128) and one movable portion (lower portion 132). In such embodiments, the spring mechanisms 112 are configured such that the upper portion 128 and the lower portion 132 are always in electrical contact with one another. However, in alternative embodiments of the present disclosure, the spring mechanisms 112 can have different configurations and arrangements so long as each spring mechanism 112 is configured to exert a spring force in a direction perpendicular to the lowermost surface 106 of the housing 104. In accordance with at least one embodiment of the present disclosure, the spring mechanisms 112 can be, for example, pogo pins.

Regardless of the particular configuration and arrangement of the spring mechanisms 112, in addition to exerting a spring force in a direction perpendicular to the lowermost surface 106 of the housing, the spring mechanisms 112 are further configured to always conduct electricity therethrough. Accordingly, the spring mechanisms 112 (including, in embodiments such as that shown, upper portion 128 and lower portion 132) are made of an electrically conductive material.

FIG. 3 illustrates the device 100 as part of a system 200 that also includes the PCB 160. In other words, the high-speed signal measurement system 200 shown in FIG. 3 includes the high-speed signal measurement device 100 and the PCB 160. Notably, the conductive probe tips 180 can be independently provided. In other words, in accordance with at least one embodiment of the present disclosure, the device 100 and system 200 are configured to be compatible with existing conductive probe tips and do not need to be specifically configured for operation with a particular probe tip. This configuration advantageously enables the device 100 and system 200 to be compatible with a variety of existing probe tips, thereby increasing the usability of the device 100 and system 200.

As shown in FIG. 3, the PCB 160 includes at least one conductive pad 164. The at least one conductive pad 164 conducts the high-speed signal that is to be measured. Accordingly, the high-speed signal measurement device 100 is configured to establish and maintain electrical contact between the conductive pad 164 and a respective conductive probe tip 180 when the device 100 is coupled to the PCB 160 and when a conductive probe tip 180 is retained within the device 100. In the illustrative embodiment shown, the PCB 160 includes two conductive pads 164, which advantageously enables the measurement of differential signals. However, alternative embodiments of the PCB 160 can include more or fewer than two conductive pads 164.

More specifically, the PCB 160 includes at least one surface mounting component 168 configured to removably matingly couple with the corresponding mounting component 102 of the device 100. In the example embodiment shown in FIG. 3, the PCB includes two surface mounting components 168. In accordance with at least one embodiment of the present disclosure, the surface mounting components 168 are integrally formed with the PCB 160. In accordance with at least one alternative embodiment of the present disclosure, the surface mounting components 168 are separately formed and are securely attached to the PCB 160.

The surface mounting components 168 can be, for example, surface mounted clips that are soldered or otherwise securely attached to the PCB 160 by the PCB manufacturer. Alternatively, the surface mounting components 168 can be, for example, adhesive regions or hook-and-loop regions. The surface mounting components 168 can have a variety of elements and configurations so long as the surface mounting components 168 are configured to removably matingly couple with the mounting components 102. In accordance with at least some embodiments of the present disclosure, the surface mounting components 168 can be configured to removably matingly engage with the mounting components 102 using one or more of screws, suction force, magnetic force, or another mechanical retention mechanism, for example.

In the embodiment shown, the surface mounting components 168 are configured so as to be arranged on lateral sides of the housing 104 when the device 100 is coupled to the PCB 160. In accordance with alternative embodiments of the present disclosure, the surface mounting components 168 may be configured so as to be arranged between the bottom of the housing 104 and the top of the PCB 160 when the device 100 is coupled to the PCB 160.

As shown, when the device 100 is coupled to the PCB 160, the mounting components 102 and the surface mounting components 168 are configured to engage one another to removably couple the device 100 to the PCB 160. This cooperation advantageously enables the device 100 to be movable to multiple locations on a PCB 160 to measure a variety of signals thereon. Additionally, when the device 100 is coupled to the PCB 160 the alignment of the mounting components 102 and the surface mounting components 168 ensures the alignment of the spring mechanisms 112 with the conductive pads 164 to facilitate signal measurements.

More specifically, when the device 100 is coupled to the PCB 160, each spring mechanism 112 is brought into electrical contact with the corresponding conductive pad 164. More specifically, the lowermost surface 114 of the spring mechanism 112 is brought into electrical contact with the conductive pad 164. As described above, the lowermost surface 114 of the spring mechanism 112 is electrically conductive. Accordingly, by bringing the lowermost surface 114 of the spring mechanism 112 into electrical contact with the conductive pad 164, the device 100 conducts the signal of the conductive pad 164 through the housing 104, from the PCB 160 to the conductive probe tip 180.

In the illustrative embodiment described herein, the lowermost surface 114 of the spring mechanism 112 is brought into direct contact with the conductive pad 164. As used herein, the term “direct contact” refers to the physical touching of two surfaces without the presence of any additional layers, features, or materials therebetween. In accordance with at least one alternative embodiment, the spring mechanism 112 can be in indirect contact with the conductive pad 164 so long as the spring mechanism 112 is still able to electrically conduct the signal from the conductive pad 164.

As described above, the spring mechanism 112 is configured to exert a spring force in a direction perpendicular to the lowermost surface 106 of the housing 104 when the spring mechanisms 112 are compressed, as they are when the device 100 is coupled to the PCB 160. Accordingly, the spring mechanisms 112 are configured to facilitate robust electrical contact with the conductive pads 164 and to maintain the electrical connection through the spring mechanisms 112 and through the housing 104 when the device 100 is coupled to the PCB 160.

As shown in FIG. 3, the clamps 108 are configured to facilitate and maintain electrical connection of the conductive probe tips 180 with the uppermost surfaces 113 of respective spring mechanisms 112. Accordingly, as described above, each of the clamps 108 is individually movable between the open position (illustrated by the rightmost clamp), in which the clamp 108 is configured to removably receive a conductive probe tip 180, and the closed position (illustrated by the leftmost clamp), in which the clamp 108 is configured to retain the conductive probe tip 180. More specifically, in the closed position, the clamp 108 retains the conductive probe tip 180 in electrical contact with the uppermost surface 113 of the spring mechanism 112.

In the illustrative embodiment described herein, the uppermost surface 113 of the spring mechanism 112 is brought into direct contact with the conductive probe tip 180. However, in accordance with at least one alternative embodiment, the spring mechanism 112 can be in indirect contact with the conductive probe tip 180 so long as the spring mechanism 112 is still able to electrically conduct the signal to the conductive probe tip 180. For example, in accordance with at least one embodiment of the present disclosure, the device 100 can include a conductive surface arranged so as to be interposed between the conductive probe tip 180 and the spring mechanism 112. In such embodiments, the clamps 108 ensure electrical contact between the conductive probe tip 180 and the conductive surface.

Accordingly, the measurement device 100 is configured to establish an electrically conductive connection between each conductive probe tip 180 and a respective conductive pad 164 when the device 100 is coupled to the PCB 160 and when a respective clamp 108 is in a closed position and is retaining the conductive probe tip 180 within the device 100.

By providing a removable engagement between the mounting components 102 on the housing 104 and the surface mounting components 168 on the PCB 160, the device 100 is removably attachable to the PCB 160. As a result, the device 100 and system 200 disclosed herein achieve the electrical connection required for obtaining high-speed signal measurements between conductive probe tips 180 and the PCB 160 without requiring soldering on the PCB 160. In this way, the disclosure enables high-speed signal measurements that do not require the time and skill of an advanced soldering technician. Additionally, the device 100 and system 200 disclosed herein do not introduce the risk of damage to the PCB 160 due to heat exposure for each signal measurement. Additionally, because they are easily removable and replaceable, the device 100 and system 200 disclosed herein are suitable for production PCBs in addition to test vehicles and are suitable for mid bus probing.

Moreover, the arrangement and configuration of the device 100 so as to electrically couple existing, separately provided conductive probe tips 180 to the conductive pads 164 of the PCB 160 using the conductive spring mechanisms 112 avoids significant consideration in the PCB layout design to accommodate complex interface devices and integrated mating connectors. Accordingly, the device 100 and system 200 disclosed herein do not require complex footprints that introduce signal reflections, and therefore minimize generation of their own signal interference issues. Additionally, the device 100 and system 200 are thereby usable with a variety of commercially available probes, for example, from multiple different vendors.

An additional advantage of the spring mechanism 112 is its ability to ensure robust electrical contact between the conductive pad 164 of the PCB 160 and the conductive probe tips 180 with a low risk of damage to the conductive pad 164, because the spring mechanism 112 is configured to be compressed by contact with the PCB 160.

An additional advantage of the device 100 and system 200 disclosed herein is the ability to removably couple the device 100 to a wider variety of locations on the PCB 160. More specifically, when probe tips are coupled to a PCB for signal measurements, it is typically required to be soldered with a via. However, by eliminating the need for soldering the probe tips to the PCB, the flexibility of locations is improved. In particular, surface mounting components 168 can be arranged anywhere on the PCB 160 where conductive pads 164 are accessible for measurement. Accordingly, the disclosed device 100 and system 200 enable signal measurement in open-area locations of the PCB 160, away from vias.

An additional advantage of the disclosed device 100 is the ability of the housing 104 to be formed by additive manufacturing. This advantage is even more pronounced for embodiments wherein at least one of latches 120, clamps 108, and mounting components 102 are integrally formed, and thereby also formed by additive manufacturing, with the housing 104. Moreover, precision additive manufacturing of the device 100 enables precision mating between conductive probe tips 180 and clamps 108. Thus, in accordance with at least some embodiments of the present disclosure, the clamps 108 could be formed having a particular configuration to improve the clamps' reception of a particular type of probe tip 180 and, thus, the electrical connection between a particular type of probe tip 180 and the conductive pad 164. In other words, an additional advantage of the disclosed device 100 is that the clamps 108 can be easily customized to optimize electrical contact for various test scenarios.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding of the various embodiments. But, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A high-speed signal measurement system, comprising:
a printed circuit board including a conductive pad; and
a measurement device configured to be removably coupled to the printed circuit board, the measurement device configured to establish an electrical connection between a conductive probe tip and the conductive pad, the measurement device including:
a clamp movable between an open position in which the measurement device is configured to removably receive the conductive probe tip and a closed position in which the measurement device is configured to retain the conductive probe tip, and
a spring mechanism configured to exert a spring force to maintain the electrical connection between the conductive probe tip and the conductive pad when the measurement device is coupled to the printed circuit board and the clamp is in the closed position.

2. The high-speed signal measurement system of claim 1, wherein:
the measurement device further includes a housing; and
the clamp is pivotally connected to the housing such that the clamp rotates relative to the housing to move between the open position and the closed position.

3. The high-speed signal measurement system of claim 2, wherein:
the measurement device further includes a latch arranged on the housing, the latch configured to removably retain the clamp in the closed position.

4. The high-speed signal measurement system of claim 2, wherein:
the spring mechanism is arranged within the housing such that the spring mechanism is in direct contact with the conductive pad when the measurement device is coupled to the printed circuit board.

5. The high-speed signal measurement system of claim 4, wherein:
the spring mechanism is in direct contact with the conductive probe tip when the conductive probe tip is retained within the measurement device.

6. The high-speed signal measurement system of claim 2, wherein:
the printed circuit board further includes a surface mounting component configured to removably matingly couple with the housing of the measurement device.

7. The high-speed signal measurement system of claim 2, wherein:
the conductive pad is arranged on a top surface of the printed circuit board;
the housing includes a lowermost surface that faces toward the top surface of the printed circuit board when the measurement device is coupled to the printed circuit board;
the housing includes an opening in the lowermost surface; and
the spring mechanism extends through the opening.

8. A high-speed signal measurement device, comprising:
a housing configured to be removably coupled to a printed circuit board;
a clamp pivotally coupled to the housing so as to be rotatable between an open position in which the measurement device is configured to receive a conductive probe tip and a closed position in which the measurement device is configured to retain the conductive probe tip; and
a spring mechanism configured to establish an electrical connection between a conductive pad on the printed circuit board and the conductive probe tip when the housing is coupled to the printed circuit board and the clamp is in the closed position.

9. The high-speed signal measurement device of claim 8, wherein:
the spring mechanism is in direct contact with the conductive pad when the housing is coupled to the printed circuit board.

10. The high-speed signal measurement device of claim 8, wherein:
the spring mechanism is in direct contact with the conductive probe tip when the conductive probe tip is retained within the measurement device.

11. The high-speed signal measurement device of claim 8, further comprising:
a latch arranged on the housing and configured to removably retain the clamp in the closed position.

12. The high-speed signal measurement device of claim 8, wherein:
the housing includes a mounting component configured to be removably matingly coupled with a surface mounting component on the printed circuit board.

13. The high-speed signal measurement device of claim 8, wherein:
the housing includes a lowermost surface that faces toward the printed circuit board when the housing is coupled to the printed circuit board;
the housing includes an opening in the lowermost surface; and
the spring mechanism extends through the opening.

14. The high-speed signal measurement device of claim 8, further comprising:
a further clamp pivotally coupled to the housing so as to be rotatable between an open position in which the measurement device is configured to receive a further conductive probe tip and a closed position in which the measurement device is configured to retain the further conductive probe tip; and
a further spring mechanism configured to establish an electrical connection between a further conductive pad on the printed circuit board and the further conductive probe tip when the housing is coupled to the printed circuit board and the further clamp is in the closed position.

15. A high-speed signal measurement device comprising:
a housing configured to be removably coupled to a printed circuit board, a height of the housing extending from an uppermost surface of the housing to a lowermost surface of the housing;
a clamp pivotally coupled to the uppermost surface so as to be rotatable between an open position in which the measurement device is configured to receive a conductive probe tip and a closed position in which the measurement device is configured to retain the conductive probe tip; and
a spring mechanism configured to exert a spring force in a direction perpendicular to the lowermost surface to establish an electrical connection between a conductive pad on the printed circuit board and the conductive probe tip when the housing is coupled to the printed circuit board and the clamp is in the closed position.

16. The high-speed signal measurement device of claim 15, wherein:
a height of the spring mechanism extends from the conductive pad on the printed circuit board and the conductive probe tip when the housing is coupled to the printed circuit board and the clamp is in the closed position, and
the height of the spring mechanism is at least as large as the height of the housing.

17. The high-speed signal measurement device of claim 16, wherein:
the height of the spring mechanism is larger than the height of the housing.

18. The high-speed signal measurement device of claim 15, further comprising:
a latch arranged on the housing and configured to removably retain the clamp in the closed position.

19. The high-speed signal measurement device of claim 15, wherein:
the housing includes a mounting component configured to be removably matingly coupled with a surface mounting component on the printed circuit board.

20. The high-speed signal measurement device of claim 15, wherein:
the lowermost surface faces toward the printed circuit board when the housing is coupled to the printed circuit board;
the housing includes an opening in the lowermost surface; and
the spring mechanism extends through the opening.
